(19) United States
(12) Patent Application Publication
(10) Pub. No.: US 2013/0335170 A1
(43) Pub. Date: Dec. 19, 2013

(54) ACOUSTIC WAVE ELEMENT AND ACOUSTIC WAVE DEVICE USING SAME

(71) Applicants: Takanori Ikuta, Kyoto (JP); Hiroyuki Tanaka, Kyoto (JP)

(72) Inventors: Takanori Ikuta, Kyoto (JP); Hiroyuki Tanaka, Kyoto (JP)

(73) Assignee: KYOCERA CORPORATION, Kyoto-shi, Kyoto (JP)

(21) Appl. No.: 13/982,238

(22) PCT Filed: Jan. 17, 2012
(86) PCT No.: PCT/JP2012/050821

§ 371 Date: Jul. 26, 2013

(30) Foreign Application Priority Data
Jan. 27, 2011 (JP) 2011-015649

(51) Int. Cl. H03H 9/64

(52) U.S. Cl. CPC H03H 9/0296
USPC 333/193; 333/195

(57) ABSTRACT

A SAW element has a substrate, electrode fingers on an upper surface of the substrate, and mass-adding films on upper surfaces of the electrode fingers. When viewing the cross-sections perpendicular to the extending directions of the electrode fingers, the mass-adding films have the narrowest widths at an upper sides in the cross-sections. By arranging the mass-adding films having such shape on the upper surfaces of the electrode fingers, the electromechanical coupling factor can be made high.

### TECHNICAL FIELD

The present invention relates to an acoustic wave element such as a surface acoustic wave (SAW) element and an acoustic wave device using the same.

### BACKGROUND ART

Known in the art is an acoustic wave element which has a piezoelectric substrate and an IDT (interdigital transducer) electrode (excitation electrode) which is provided on a major surface of the piezoelectric substrate (for example, Patent Literature 1 or 2). The IDT electrode has a plurality of electrode fingers which extend in a direction perpendicular to the direction of advance of the acoustic wave. Further, the acoustic wave element utilizes the piezoelectric effect to convert an electrical signal to an acoustic wave and convert an acoustic wave to an electrical signal.

Note that, in the arts of Patent Literature 1 and Patent Literature 2, a protective layer made of SiO₂ (SiO₂ film) is covered on the major surface of the piezoelectric substrate from the top of the IDT electrode. The protective layer contributes to suppression of corrosion of the IDT electrode, compensation for a change of characteristics of the IDT electrode according to a change of temperature, and so on. Further, in order to improve contact between the IDT electrode and the protective layer, Patent Literature 1 and Patent Literature 2 propose formation of a bonding layer between them (paragraph 0011 in Patent Literature 1 and paragraph 0107 in Patent Literature 2). In Patent Literature 1 and Patent Literature 2, the bonding layer is formed thin so as not to exert an influence upon the propagation of the SAW. Specifically, the bonding layer is controlled to 50 to 100 Å (paragraph 0009 in Patent Literature 1) or 1% or less based on the wavelength of the SAW (paragraph 0108 in Patent Literature 2).

In the acoustic wave element, improvement of the electromechanical coupling factor is sometimes desired. For example, by making the electromechanical coupling factor large, a high bandwidth filter can be realized.

Accordingly, desirably there are provided an acoustic wave element and acoustic wave device capable of raising the electromechanical coupling factor.

### CITATIONS LIST

### Patent Literature

Patent Literature 1: Japanese Patent Publication No. 8-204493A
Patent Literature 2: Japanese Patent Publication No. 2004-112748A

### SUMMARY OF INVENTION

An acoustic wave element according to an aspect of the present invention has a piezoelectric substrate, electrode fingers arranged on an upper surface of the piezoelectric substrate, and mass-adding films arranged on the upper surfaces of the electrode fingers, wherein, when viewing cross-sections perpendicular to the extending directions of the electrode fingers, the mass-adding films have the narrowest widths at an upper sides in the cross-sections.

An acoustic wave device according to an aspect of the present invention has the above acoustic wave element and a circuit board to which the acoustic wave element is attached.

According to the above configuration, by arranging the mass-adding films on the upper surfaces of the electrode fingers and making the widths of the mass-adding films narrowest at the upper sides on their cross-sections when viewing cross-sections perpendicular to the extending directions of the electrode fingers, the electromechanical coupling factor can be made high.

### BRIEF DESCRIPTION OF DRAWINGS

FIG. 1A is a plan view of a SAW element according to an embodiment of the present invention, and FIG. 1B is a cross-sectional view taken along an Ib-Ib line in FIG. 1A.

FIG. 2A to FIG. 2E are cross-sectional views explaining a method of production of a SAW element and corresponding to FIG. 1B.

FIG. 3A and FIG. 3B are cross-sectional views for explaining an example of a method of forming a mass-adding film to a trapezoidal shape.

FIG. 4A and FIG. 4B are cross-sectional views for explaining another example of the method of forming a mass-adding film to a trapezoidal shape.

FIG. 5A to FIG. 5C are diagrams for explaining the modes of operation of SAW elements of comparative examples and an embodiment.

FIG. 6A and FIG. 6B are diagrams for explaining the modes of operation of SAW elements of another comparative example and an embodiment.

FIG. 7A and FIG. 7B are diagrams showing an example of computation results for explaining the action of the SAW element of the embodiment.

FIG. 8A to FIG. 8F are cross-sectional views showing modifications of the SAW element.

FIG. 9A and FIG. 9B are graphs showing a reflection coefficient Γ₁ per electrode finger and an electromechanical coupling factor K².

FIG. 10A and FIG. 10B are other graphs showing the reflection coefficient Γ₁ per electrode finger and an electromechanical coupling factor K².

FIG. 11 Another graph showing the reflection coefficient Γ₁ per electrode finger.

FIG. 12A and FIG. 12B are diagrams for explaining how to find the lower limit of the preferred range of the thickness of a mass-adding film.

FIG. 13 A graph showing the lower limit of the example of the preferred range of the thickness of a mass-adding film.

FIG. 14 A graph showing an example of the preferred range of the thickness of a mass-adding film.

FIG. 15 A cross-sectional view showing a SAW element according to an embodiment of the present invention.

### DESCRIPTION OF EMBODIMENTS

Below, a SAW element and a SAW device according to an embodiment of the present invention is explained with reference to the drawings. Note that, the drawings used in the following explanation are diagrammatical ones. Dimensions, ratios, etc. on the drawings do not always match the actual ones.

(Configuration and Method of Production of SAW Element)

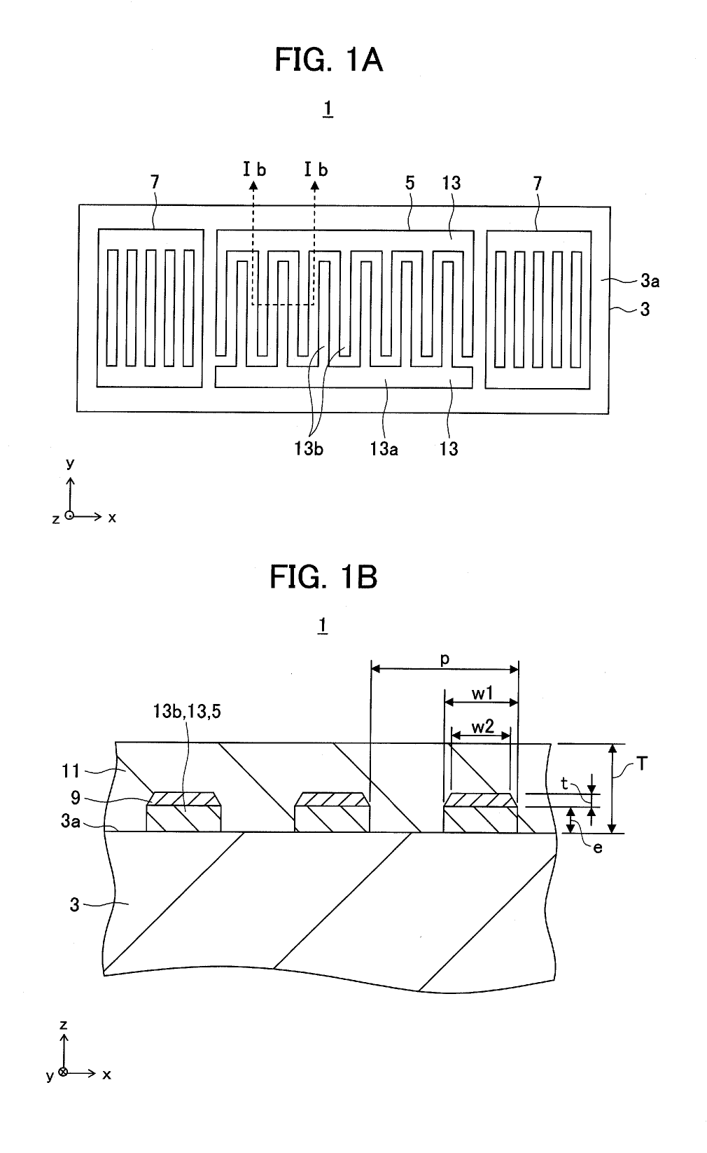

FIG. 1A is a plan view of a SAW element 1 according to an embodiment of the present invention, while FIG. 1B is a cross-sectional view taken along a line Ib-Ib in FIG. 1A. Note that, in the SAW element 1, any direction may be made upward or downward. However, for convenience, a Cartesian coordinate system xyz is defined, the positive side of the z-direction (the front side from the surface of the paper in FIG. 1A and the upper side in the surface of the paper in FIG. 1B) is defined as the upper side, and the terms “upper surface”, “lower surface”, etc. are used based on this.

The SAW element 1 has a substrate 3, an IDT electrode 5, and reflectors 7 which are provided on an upper surface 3a of the substrate 3, mass-adding films 9 (FIG. 1B) provided on the IDT electrode 5 and reflectors 7, and a protective layer 11 (FIG. 1B) covering the upper surface 3a from the tops of the mass-adding films 9. Note that, other than these, the SAW element 1 may have lines for inputting and outputting signals to and from the IDT electrode 5 and so on.

The substrate 3 is configured by a piezoelectric substrate. Specifically, for example, the substrate 3 is configured by a substrate of a single crystal having piezoelectricity such as a lithium tantalate (LiTaO₃) single crystal or lithium niobate (LiNbO₃) single crystal. More preferably, the substrate 3 is configured by a 128°±10° Y-X cut LiNbO₃ substrate. The planar shape and various dimensions of the substrate 3 may be suitably set. As an example, the thickness of the substrate 3 (z-direction) is 0.2 mm to 0.5 mm.

The IDT electrode 5 has a pair of comb-shaped electrodes 13. Each comb-shaped electrode 13 has a bus bar 13a (FIG. 1A) extending in the propagation direction of the SAW (x-direction) and a plurality of electrode fingers 13b extending from the bus bar 13a in a direction (y-direction) perpendicular to the propagation direction. Two comb-shaped electrodes 13 are provided so as to mesh with each other (so that the electrode fingers 13b cross each other).

Note that, FIG. 1A etc. are diagrammatical views. In actuality, a plurality of pairs of comb-shaped electrodes having a larger number of electrode fingers than this may be provided. Further, a ladder type SAW filter in which a plurality of IDT electrodes 5 are connected by serial connection, parallel connection, or other method may be configured or a dual mode SAW resonator filter in which a plurality of IDT electrodes 5 are arranged along the X-direction etc. may be configured. Further, by making the lengths of the plurality of electrode fingers different, weighting by apodizing may be carried out as well.

The IDT electrode 5 is formed by for example a material containing Al as a major component (including an Al alloy). The Al alloy is for example an Al—Cu alloy. Note that, the term “containing Al as a major component” means that Al is basically used as the material, but a material mixed with impurities other than Al which may be naturally mixed in during for example the manufacturing process of the SAW device 1 is included as well. Below, a case using an expression such as “a major component” means the same as well. Further, the IDT electrode 5 may be configured by a plurality of metal layers as well. The various dimensions of the IDT electrode 5 are suitably set in accordance with the electrical characteristic etc. requested from the SAW element 1. As an example, the thickness “e” of the IDT electrode 5 (FIG. 1B) is 100 nm to 300 nm.

Note that, the IDT electrode 5 may be directly arranged upon the upper surface 3a of the substrate 3 or may be arranged on the upper surface 3a of the substrate 3 through another member. The other member is for example Ti, Cr, or an alloy of the same. When the IDT electrode 5 is arranged on the upper surface 3a of the substrate 3 through another member in this way, the thickness of the other member is set to an extent such that almost no influence is exerted upon the electrical characteristics of the IDT electrode 5 (for example a thickness of 5% based on the thickness of the IDT electrode 5 in the case of Ti).

The plurality of electrode fingers 13b are provided so that their pitch (repetition interval) “p” (FIG. 1B) becomes equivalent to for example a half wavelength of the wavelength λ of the SAW at a frequency to be resonated. The wavelength λ (2p) is for example 1.5 μm to 6 μm. The width w1 (FIG. 1B) of each electrode finger 13b is suitably set in accordance with the electrical characteristics etc. required from the SAW element 1 and is for example 0.4p to 0.6p with respect to the pitch “p”.

The reflectors 7 are formed in a lattice-shape having substantially an equal pitch to the pitch “p” of the electrode fingers 13b of the IDT electrode 5. The reflectors 7 are for example formed by the same material as that of the IDT electrode 5 and are formed to a thickness equivalent to that of the IDT electrode 5.

The mass-adding films 9 are for improving the electrical characteristics of the IDT electrode 5 and the reflectors 7. The mass-adding films 9 are for example provided over the entire surfaces of the upper surfaces of the IDT electrode 5 and reflectors 7. The material configuring the mass-adding films 9 is comprised of for example a material containing as a major component a material satisfying the conditions of at least one of a material by which the propagation velocity becomes slow compared with the material configuring the IDT electrode 5 and reflectors 7 (Al or Al alloy etc.) and a material having a different acoustic impedance compared with a material configuring the IDT electrode 5 and reflectors 7 (Al or Al alloy etc.) and the material configuring the protective layer 11 (which is explained later). The difference of the acoustic impedance is preferably a certain extent or more. For example, it is preferably 15 MRayl or more, more preferably 20 MRayl or more. The preferred material of the mass-adding films 9 and the preferred thickness “t” (FIG. 1B) of the mass-adding films 9 are explained later.

The mass-adding films 9 are formed so that the widths in the cross-sections become the narrowest at the upper sides when viewing the cross-sections in a direction perpendicular to the longitudinal directions (y-directions) of the electrode fingers 13b. Further, the widths in the cross-sections become larger at the lower sides than that at the upper sides. In other words, the mass-adding films 9 are formed narrower at the upper surface side portions than the lower surface side portions when viewed in the y-directions. In the SAW element 1, the cross-sectional shapes of the mass-adding films 9 become trapezoidal shapes. The lengths of the lower bases of the trapezoidal shapes of the mass-adding films 9 are for example equivalent to the widths w1 of the electrode fingers 13b. The preferred range of the lengths of the upper bases of the trapezoidal shapes (widths w2) is explained later.

The protective layer 11 is for example provided over substantially the entire surface of the upper surface 3a of the substrate 3, covers the IDT electrode 9 and reflectors 7 which are provided with the mass-adding films 9, and covers the portion of the upper surface 3a which is exposed from the IDT electrode 5 and the reflectors 7. The thickness T (FIG. 1B) from the upper surface 3a of the protective layer 11 is set larger than the thickness “e” of the IDT electrode 5 and reflectors 7. For example, the thickness T is thicker than the thickness “e” by 100 nm or more and is 200 nm to 700 nm.

The protective layer 11 is made of a material containing as a major component a material having an insulation property. Preferably, the protective layer 11 is formed by a material containing as a major component a material by which the propagation velocity of the acoustic wave becomes fast when the temperature rises such as SiO₂. The change of the characteristics according to the change of the temperature can be kept small by this. That is, an acoustic wave element excellent in temperature compensation can be obtained. Note that, in the material configuring the substrate 3 and other general material, the propagation velocity of the acoustic wave becomes slow when the temperature rises.

Further, the surface of the protective layer 11 is desirably made free from large concave-convex shapes. The propagation velocity of the acoustic wave propagating on the piezoelectric substrate changes when influenced by concave-convex shapes of the surface of the protective layer 11. Therefore, if large concave-convex shapes exist on the surface of the protective layer 11, there arises a large variation in the resonant frequencies of produced acoustic wave elements. Accordingly, when making the surface of the protective layer 11 flat, the resonant frequency of each acoustic wave element is stabilized. Specifically, desirably the flatness of the surface of the protective layer 11 is made 1% or less based on the wavelength of the acoustic wave propagating on the piezoelectric substrate.

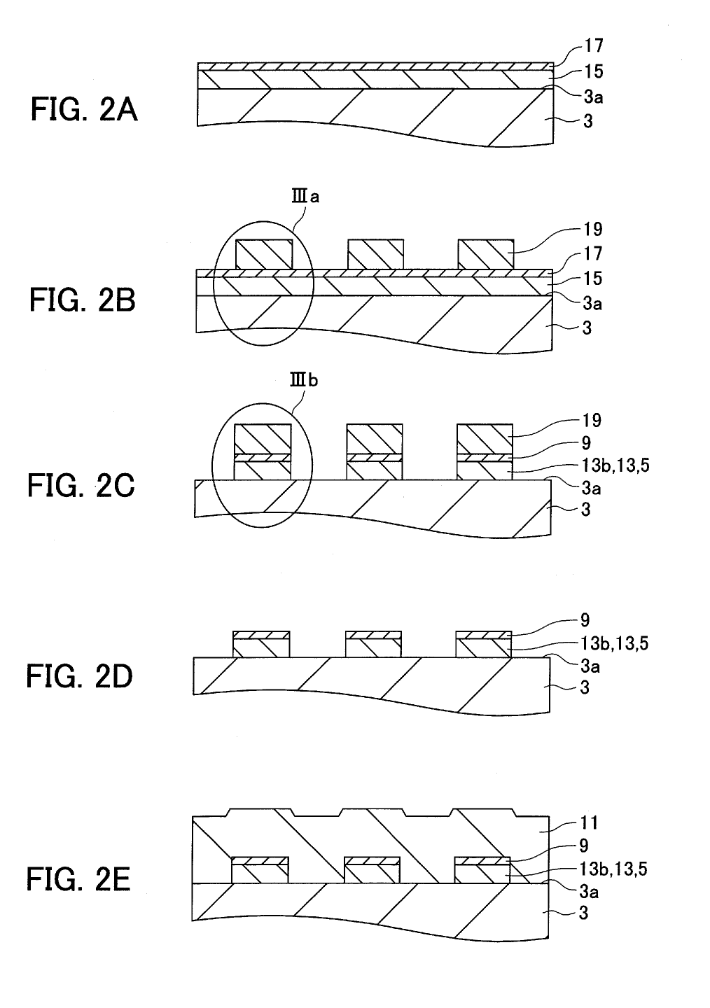

FIG. 2A to FIG. 2E are cross-sectional views explaining the method of production of the SAW element 1 and corresponding to FIG. 1B for each manufacturing process. The manufacturing process advances from FIG. 2A to FIG. 2E in order. Note that, various types of layers change in shapes etc. along with the advance of the process. However, common notations will be sometimes used before and after the change.

As shown in FIG. 2A, first, on the upper surface 3a of the substrate 3, a conductive layer 15 which becomes the IDT electrode 5 and reflectors 7 and an additional layer 17 which becomes the mass-adding films 9 are formed. Specifically, first, by a thin film forming method such as a sputtering process, a vapor deposition process, or a CVD (chemical vapor deposition) process, the conductive layer 15 is formed on the upper surface 3a. Next, by the same thin film forming method, the additional layer 17 is formed.

When the additional layer 17 is formed, as shown in FIG. 2B, a resist layer 19 serving as a mask for etching the additional layer 17 and conductive layer 15 is formed. Specifically a thin film of a negative type or positive type photosensitive resin is formed by a suitable thin film forming method. A portion of the thin film is removed by a photolithography method or the like at the position where the IDT electrode 5 and reflectors 7 etc. are not arranged.

Next, as shown in FIG. 2C, by a suitable etching method such as an RIE (reactive ion etching), the additional layer 17 and conductive layer 15 are etched. Due to this, the IDT electrode 5 and reflectors 7 which are provided with the mass-adding films 9 are formed. After that, as shown in FIG. 2D, by using a suitable chemical solution, the resist layer 19 is removed.

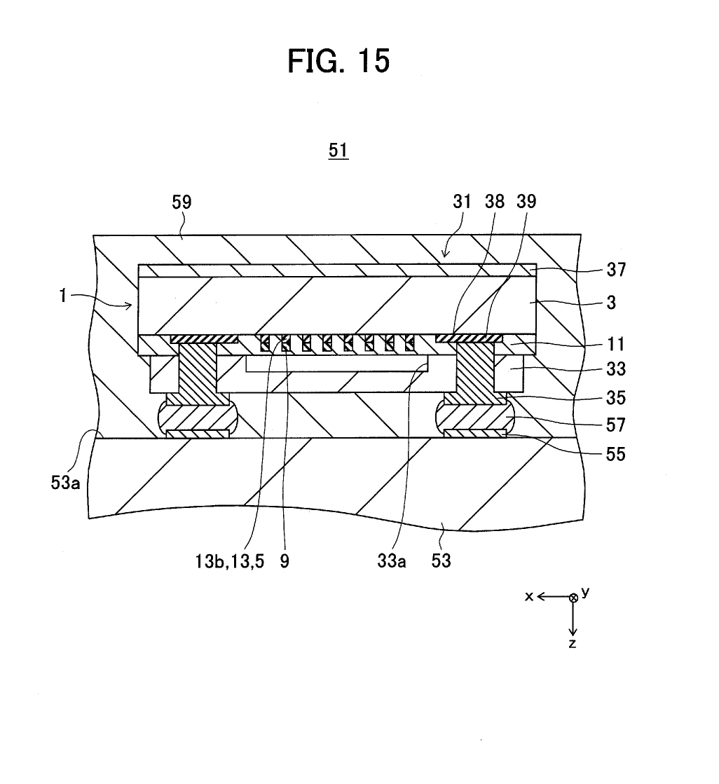

Further, as shown in FIG. 2E, by a suitable thin film forming method such as the sputtering process or the CVD process, a thin film which becomes the protective layer 11 is formed. At this point of time, concave-convex shapes are formed on the surface of the thin film which becomes the protective layer 11 due to thicknesses of the IDT electrode 5 etc. Further, according to need, the surface is flattened by chemical mechanical polishing or the like, whereby the protective layer 11 is formed as shown in FIG. 1B. Note that, in the protective layer 11, before or after flattening, a portion may be removed by the photolithography process or the like in order to expose a pad 39 (FIG. 15) etc. which will be explained later.

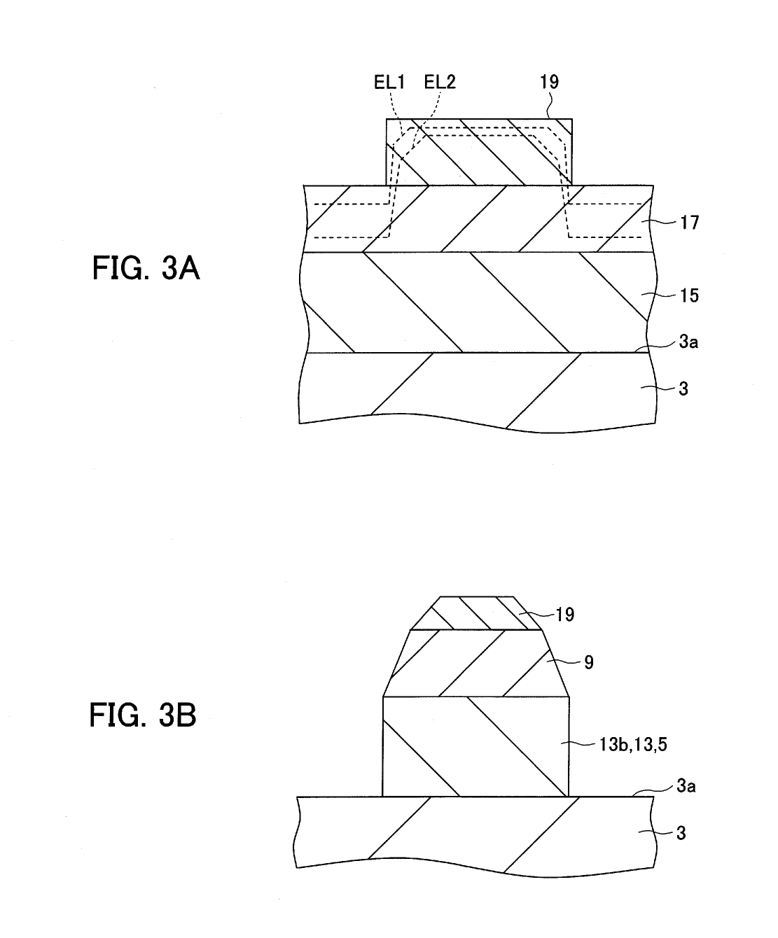

FIG. 3A and FIG. 3B are diagrams for explaining an example of a method of forming a mass-adding film 9 to a trapezoidal shape. Specifically, FIG. 3A is enlarged view of a region IIIa in FIG. 2B, while FIG. 3B is an enlarged view of a region IIIb in FIG. 2C.

In etching of the additional layer 17 and conductive layer 15, the resist layer 19 which serves as the mask is etched as well though the extent is very small. Accordingly, as shown in FIG. 3A, the surface shapes of the resist layer 19 and additional layer 17 which are indicated by solid lines sequentially change along with the advance of etching from the shapes indicated by a dotted line EL1 to the shapes indicated by a dotted line EL2.

That is, in an initial stage of etching (resist layer 19 indicated by the solid line in FIG. 3A), the additional layer 17 which was located under the periphery of the bottom surface of the resist layer 19 becomes exposed. When this portion is etched and the etching further advances, next the additional layer 17 which was located under the periphery of the bottom surface of the resist layer 19 which was etched a bit (the resist layer 19 indicated by the dotted line EL1 in FIG. 3A) becomes exposed. By etching of this portion and gradual advance of such etching, a trapezoid-shaped mass-adding film 9 is obtained.

Therefore, if the etching conditions (for example ratio of composition of etching gas and applied voltage in the case of etching by RIE) are set so that the side surface of the resist layer 19 is etched much more, the side surface of the resist layer 19 exhibits a more inclined state. The side surfaces of the mass-adding film 9 are inclined more along with this. That is, by changing the conditions of etching, the shape of the mass-adding film 9 can be controlled.

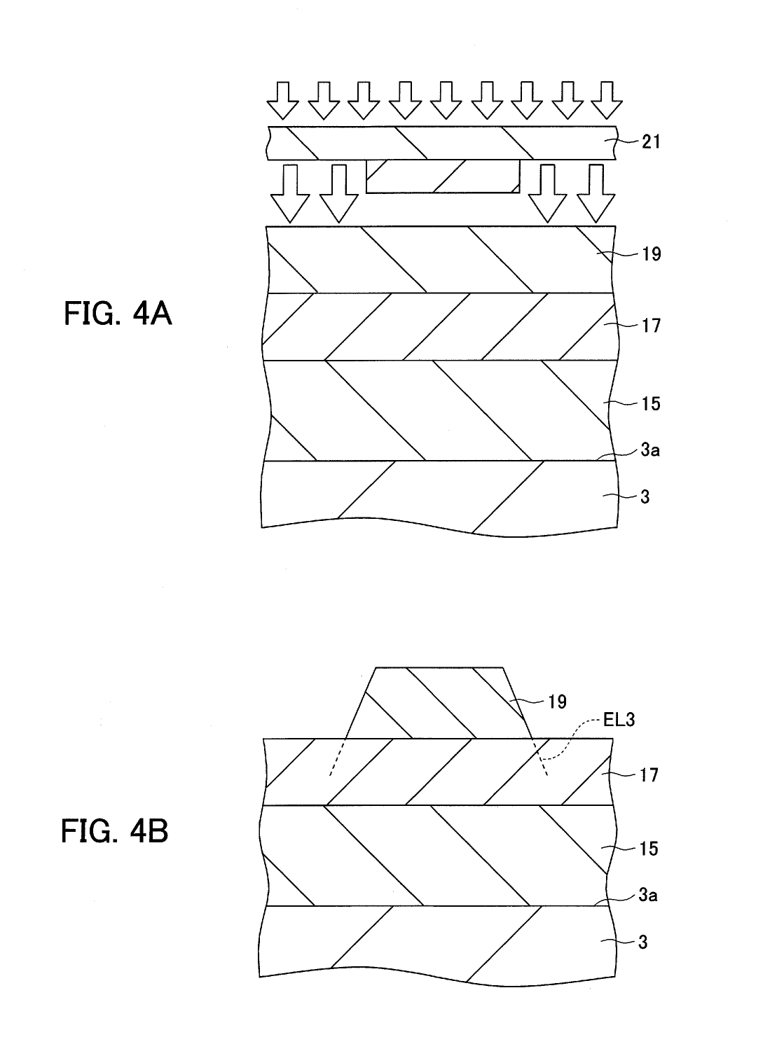

FIG. 4A and FIG. 4B are diagrams for explaining another example of the method of forming a mass-adding film 9 a trapezoidal shape. Specifically, FIG. 4A is a diagram corresponding to the enlarged view of the region 111a in FIG. 2B during a transition from FIG. 2A to FIG. 2B (exposure process), and FIG. 4B is an enlarged view of the region 111a in FIG. 2B.

In this example, the resist layer 19 is formed by positive type photolithography. Accordingly, as shown in FIG. 4A, light is irradiated through the mask 21 to positions where the IDT electrode 5 etc. are not arranged. Further, by removal of the portions to which the light was irradiated, the resist layer 19 has a shape shown in FIG. 4B.

At this time, the resist layer 19 located under the light-shielding part of the mask 21 is basically not removed since it is not irradiated by light, but the portions located under the periphery of the light-shielding part of the mask 21 are removed at their upper surface sides since they are irradiated by the light diffracted at the edges of the light-shielding part. As a result, the resist layer 19 has a trapezoidal shape in which the upper surface side portion is smaller than the lower surface side portion. Further, as explained in FIG. 3, it becomes easy to make the etching direction of the additional layer 17 incline. The additional layer 17 is etched to a trapezoidal shape as indicated by the dotted line EL3 in FIG. 4B. Note that, in this example as well, by changing the exposure conditions etc., the shape of the mass-adding film 9 can be controlled.

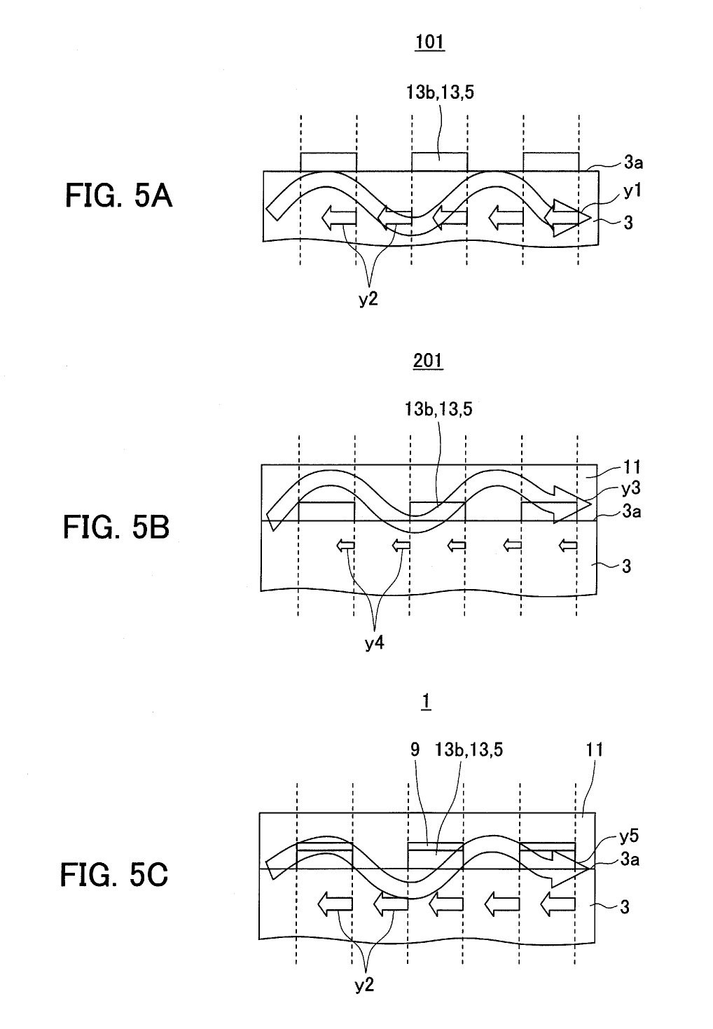

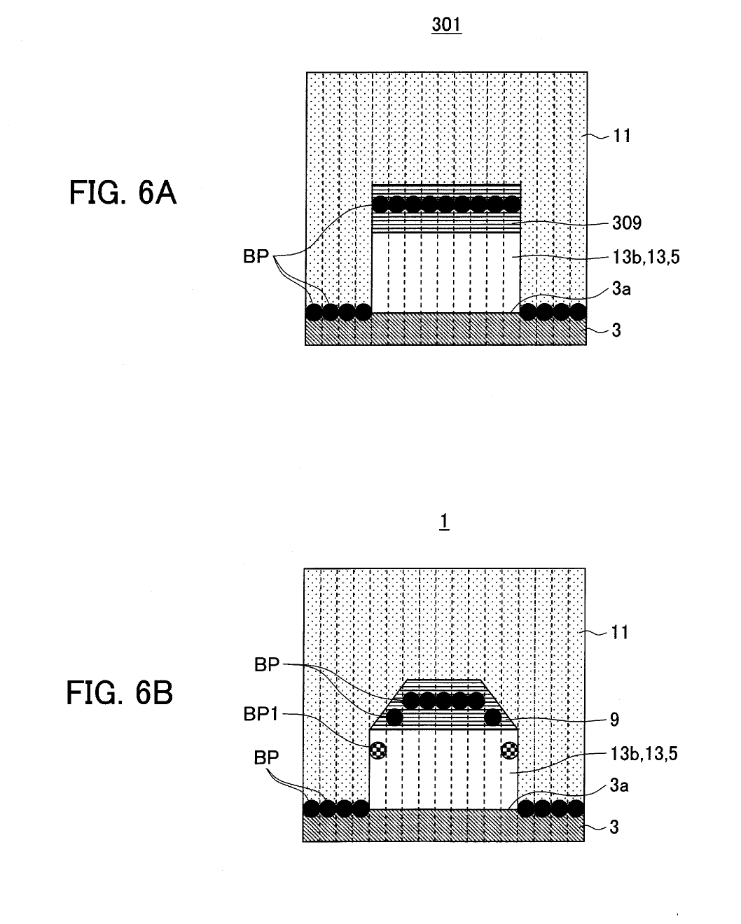

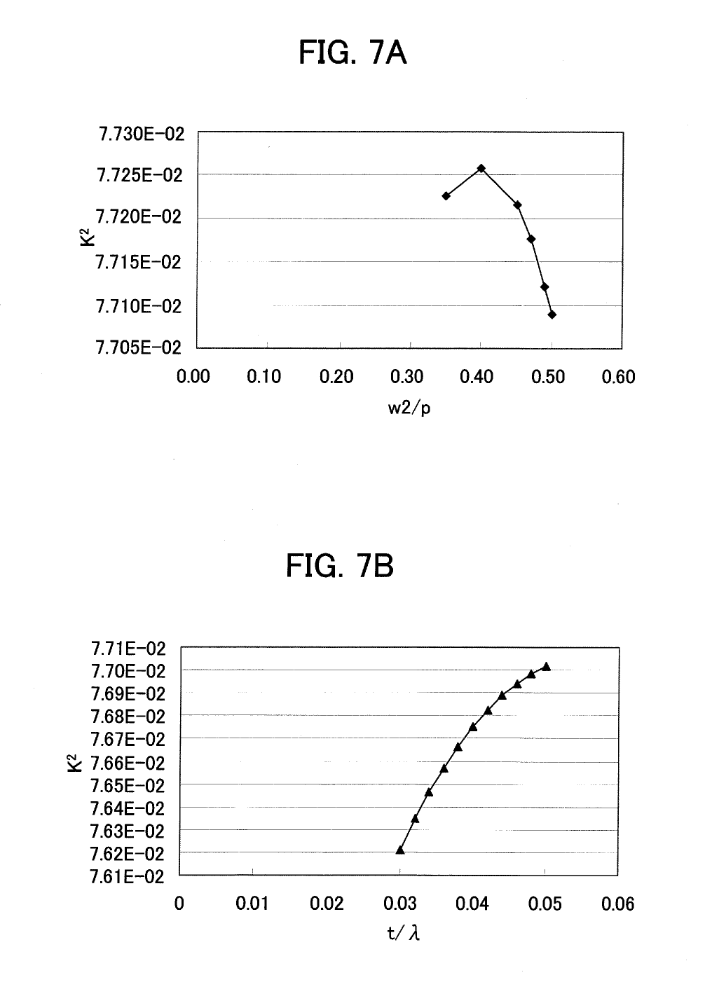

Referring to FIG. 5A to FIG. 5C, FIG. 6A and FIG. 6B, and FIG. 7A and FIG. 7B, the modes of operation of comparative examples will be explained, and the action of the SAW element 1 of the embodiment will be explained.

FIG. 5A is a cross-sectional view for explaining the action of a SAW element 101 of a first comparative example. The SAW element 101 is comprised of the SAW element 1 of the first embodiment in a state with no mass-adding films 9 and protective layer 11.

When voltage is applied to the substrate 3 by the IDT electrode 5, as indicated by an arrow y1, near the upper surface 3a of the substrate 3, a SAW propagating along the upper surface 3a is induced. Further, as indicated by the arrows y2, the SAW is reflected at a boundary between an electrode finger 13b and a gap portion (a region in which no electrode finger 13b is arranged). Further, a standing wave which has the pitch of the electrode fingers 13b as the half wavelength is formed by the SAW indicated by the arrows y1 and y2. The standing wave is converted to an electrical signal having the same frequency as that of the standing wave and is extracted by the electrode fingers 13b. In this way, the SAW element 1 functions as a resonator or filter.

In the SAW element 101, however, when the temperature rises, the propagation velocity of the acoustic wave on the substrate 3 becomes slow, and the gap portion becomes large. As a result, the resonant frequency becomes low, so the desired characteristics are liable to not be obtained. Further, the IDT electrode 5 is exposed upward, therefore it easily contacts moisture, so it is liable to corrode.

FIG. 5B is a cross-sectional view for explaining the action of a SAW element 201 of a second comparative example. The SAW element 201 is comprised of the SAW element 1 of the first embodiment in a state with no mass-adding film 9. In other words, it comprises the SAW element 101 of the first comparative example to which the protective layer 11 is added.

In the SAW element 201, since the protective layer 11 is provided, as indicated by the arrow y3, the induced SAW is propagated not only on the substrate 3, but also on the protective layer 11. Here, for example, the protective layer is formed by the material by which the propagation velocity of the acoustic wave becomes faster when the temperature rises such as SiO₂. Accordingly, in the SAW as a whole which propagates on the substrate 3 and the protective layer 11, the change of the velocity due to the temperature rise is suppressed. That is, by the protective layer 11, the change of characteristics of the substrate 3 due to a temperature rise is compensated for. Further, by the protective layer 11, the probability of contact of the IDT electrode 5 with moisture is reduced, and consequently the liability of corrosion is reduced.

However, if the vibration of the SAW is transferred from the substrate 3 to the protective layer 11 too much, the conversion from the SAW to an electrical signal or the like is no longer carried out sufficiently. That is, the electromechanical coupling factor falls. Further, in a case where the IDT electrode 5 is formed by Al or an Al alloy and the protective layer 11 is formed by SiO₂, the acoustical properties of the IDT electrode 5 and the protective layer 11 become similar, so the boundary between an electrode finger 13b and a gap portion acoustically becomes vague. In other words, the reflection coefficient at the boundary between an electrode finger 13b and a gap portion falls. As a result, as indicated by the arrows y4 in FIG. 5B which are smaller than the arrow y2 in FIG. 5A, the reflection wave of the SAW is not sufficiently obtained, so the desired characteristics are liable to not be obtained.

FIG. 5C is a cross-sectional view for explaining the action of the SAW element 1 of the embodiment.

Since the SAW element 1 has the protective layer 11, in the same way as the SAW element 201 of the second comparative example, the effect of compensation for the temperature characteristics and so on are obtained. Further, in a case where the mass-adding films 9 are formed by a material whereby the propagation velocity of the acoustic wave becomes slower than that on the IDT electrode 5, as indicated by an arrow y5 having a position made lower than the position of the arrow y3, excessive transfer of the SAW to the protective layer 11 near the electrode finger 13b is suppressed. As a result, the electromechanical coupling factor becomes high. Further, in a case where the mass-adding films 9 are formed by a material having an acoustic impedance which is different from the acoustic impedances of the IDT electrode 5 and protective layer 11 to a certain extent, the reflection coefficient at the boundary position between an electrode finger 13b and a gap portion becomes high. As a result, as indicated by the arrows y2, it becomes possible to obtain a sufficient reflection wave of the SAW.

FIG. 6A is a cross-sectional view for explaining the action of a SAW element 301 of a third comparative example. The SAW element 301 becomes one having rectangular mass-adding films 309 in place of the trapezoidal mass-adding films 9 in the embodiment.

In FIG. 6A, the plurality of points BP show an example of the vibration center of the SAW. The SAW is distributed near the surface of the substrate 3 in regions (gap portions) in which the electrode fingers 13b are not arranged and is distributed in the mass-adding films 309 in the regions in which the electrode fingers 13b are arranged, In other words, the path of the vibration center of the SAW is separated from the surface of the substrate 3 in the regions in which the electrode fingers 13b are arranged. As a result, the electromechanical coupling factor becomes small.

FIG. 6B is a cross-sectional view for explaining the action of the SAW element 1 of the embodiment.

In FIG. 6B, the plurality of points BP (including BP1) show an example of the vibration center of the SAW. In the SAW element 1, at the boundary between the position where no electrode finger 13b is arranged and the position where it is arranged, the mass of the mass-adding film 9 becomes small. Therefore, compared with the SAW element 301, the transition of the vibration center of the SAW from the substrate 3 to the mass-adding film 9 becomes gentler, and the vibration center of the SAW passes through the electrode fingers 13b as indicated by the point BP1. That is, the vibration center of the SAW approaches the substrate 3. As a result, the electromechanical coupling factor becomes large.

FIG. 7A shows the change of the electromechanical coupling factor K² when changing the shape of the mass-adding film 9.

FIG. 7A was obtained by simulation.

The computation conditions were as follows.
Material of substrate 3: 128° Y-X cut LiNbO₃ substrate
Material of IDT electrode 5: Al
Material of protective layer 11: SiO₂
Material of mass-adding film 9: Ta₂O₅
Normalized thickness e/λ of IDT electrode 5: 0.08
Normalized thickness T/λ of protective layer 11: 0.33
Normalized thickness t/λ of mass-adding films 9: 0.05.
Normalized length w1/p of lower base of mass-adding film 9: 0.50
Normalized length w2/p of upper base of mass-adding film 9: Changed within range of 0.35 to 0.50

In FIG. 7A, the abscissa shows the normalized length w2/p of the upper base of a mass-adding film 9, while the ordinate shows the electromechanical coupling factor K². Under the computation conditions this time, when w2/p=0.5, w2/p=w1/p. That is, when w2/p=0.5, the shape of the mass-adding film is rectangular (the mass-adding film is the mass-adding film 309 in the third comparative example).

It was confirmed from this computation result that the electromechanical coupling factor K² became high by forming a mass-adding film 9 in a trapezoidal shape (by making w2/p less than 0.5). More specifically, it was confirmed that the electromechanical coupling factor K² became high when w2/w1 was 0.7 or more, but was less than 1.0. Note that, it is considered that the effect of raising the electromechanical coupling factor K² is obtained if the mass-adding film 9 is changed from a rectangular shape to a trapezoidal shape even a little. However, in simulation, it has been confirmed that the effect is manifested when w2/w1 is 0.98 (when w2/p is 0.49).

Here, when a mass-adding film 9 is formed to a trapezoidal shape, the volume of the mass-adding film 9 is reduced as well as a whole. There is a possibility that the electromechanical coupling factor K² has become high due to simple reduction of the volume of the mass-adding film irrespective of the shape of the mass-adding film. Therefore, the influence of reduction of the volume of the mass-adding film when reducing the volume of the mass-adding film 9 by changing the thickness “t” of the mass-adding film was checked.

FIG. 7B shows the change of the electromechanical coupling factor K² when the thickness “t” of the mass-adding film is changed.

FIG. 7B was obtained by simulation. Its computation conditions were substantially the same as the computation conditions in FIG. 7A except the conditions according to the mass-adding films. In the computation in FIG. 7B, the mass-adding films are formed in a rectangle shape (the mass-adding films 309 in the third comparative example). Their normalized thickness t/λ is changed within the range of 0.03 to 0.05. In FIG. 7B, the abscissa shows the normalized thickness t/λ of the mass-adding films 309, and the ordinate shows the electromechanical coupling factor K².

It is seen from FIG. 7B that the electromechanical coupling factor K² has been reduced when the volume of the mass-adding films is reduced by reducing the thickness “t” of the mass-adding films. Accordingly, it was confirmed that the improvement of the electromechanical coupling factor K² in FIG. 7A was not due to the simple reduction of the volume of the mass-adding films, but due to the change of shape thereof.

Further, in FIG. 7A, when w2/p is made smaller, the rise of the electromechanical coupling factor K² reaches the peak (w2/p=0.4). It is considered from the result in FIG. 7B that this occurs due to the reduction of the electromechanical coupling factor K² due to the reduction of the volume.

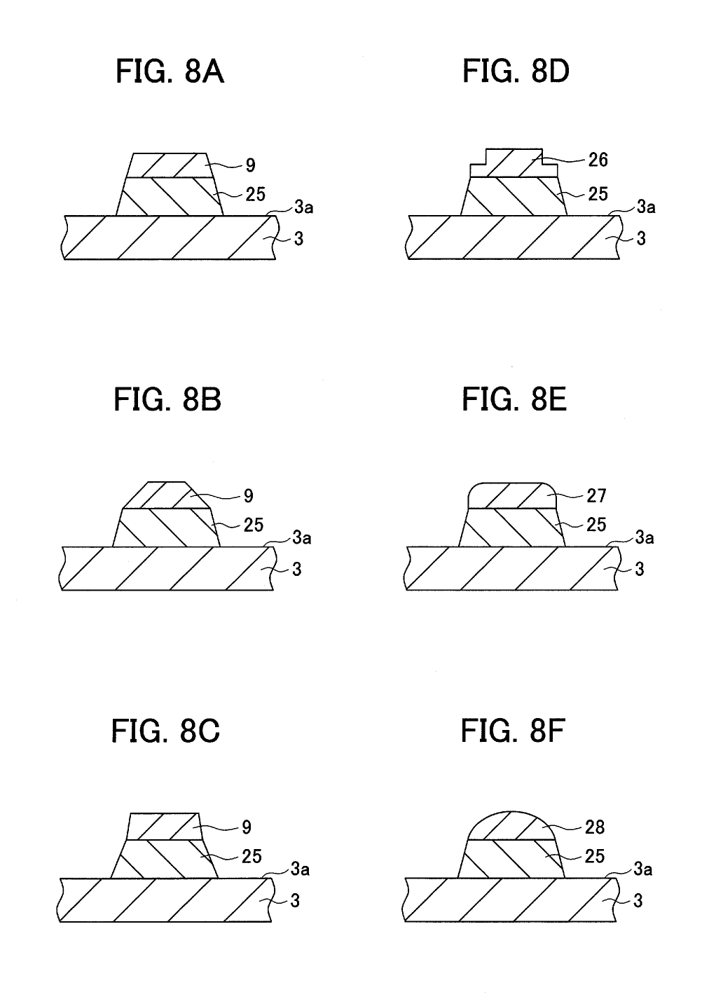

FIG. 8A to FIG. 8F are cross-sectional views showing modifications of the SAW element.

In the SAW element in FIG. 8A, the shape of the electrode finger 25 differs from the shapes of the electrode fingers 13b shown in FIG. 1B etc. Specifically, the side surfaces along the longitudinal direction of the electrode finger 25 are inclined so as to expand as they approach the upper surface of the substrate 3. More specifically, the electrode finger 25 is formed so that the cross-sectional shape becomes trapezoidal when viewing the cross-section in a direction perpendicular to the longitudinal direction of the electrode finger 25. Note that, the length of the lower base of the mass-adding film 9 is made equivalent to the length of the upper base of the electrode finger 25, and the side surfaces of the mass-adding film 9 and the electrode finger 25 are given inclination angles which are made the same as each other relative to the upper surface 3a.

The SAW elements in FIG. 8B and FIG. 8C have trapezoidal electrode fingers 25 in the same way as the SAW element in FIG. 8A. Further, the lengths of the lower bases of the mass-adding films 9 are made equivalent to the lengths of the upper bases of the electrode fingers 25. Note, in the SAW element in FIG. 8B, the inclination of the side surfaces of the mass-adding film 9 has become larger than that of the side surfaces of the electrode finger 25. Conversely, in the SAW element in FIG. 8C, the inclination of the side surfaces of the mass-adding film 9 has become smaller than that of the side surfaces of the electrode finger 25.

In all of FIG. 8A to FIG. 8C, since the upper surface side portions are made narrower than the lower surface side portions in the mass-adding films 9, as explained above, the effect of improvement of the electromechanical coupling factor K² is obtained. Further, in the electrode fingers 25 as well, since the upper surface side portions are made narrower than the lower surface side portions, the transition of the vibration center of SAW from the substrate 3 to the mass-adding films 9 becomes further gentler and consequently further improvement of the electromechanical coupling factor K² is expected.

Note that, in the same way as the mass-adding films 9, the electrode fingers 25 in FIG. 8A to FIG. 8C are formed in trapezoidal shapes by for example making the time of etching relatively short. The inclination angles of the side surfaces of the electrode fingers 25 and the mass-adding films 9 are made the same as each other or different from each other by suitably setting the etching conditions while considering the difference between the etching rates of the mass-adding films 9 and the etching rates of the electrode fingers 25. Alternatively, the inclination angles of the side surfaces of the electrode fingers 25 and the mass-adding films 9 are made the same as each other or different from each other by forming the mask and etching separately between the electrode fingers 25 and the mass-adding films 9.

The SAW elements in FIG. 8D to FIG. 8F have, in the same way as the mass-adding films 9, mass-adding films 26, 27, and 28 which are formed to be narrower in their upper surface side portions than their lower surface side portions when viewed in the longitudinal direction of the electrode fingers 25. Note, the mass-adding films 26, 27, and 28 are given shapes which are different from a trapezoidal shape.

Specifically, the mass-adding film 26 in FIG. 8D is given a shape, when viewed in the longitudinal direction of the electrode finger 25, comprised of one rectangle on which another rectangle having a narrower width is superimposed. Such a shape is realized for example by forming a mask and etching in two steps.

The mass-adding film 27 in FIG. 8E has a shape obtained by rounding the corner portions formed by its upper surface and side surfaces by a level surface or curved surface (curved surface in FIG. 8E) when viewed in the longitudinal direction of the electrode finger 25. Such a shape is realized, for example, in the same way as the trapezoidal-shape mass-adding film 9, by suitably setting the conditions of etching such as adjustment of the time of etching.

The mass-adding film 28 in FIG. 8F is substantially dome-shaped when viewed in the longitudinal direction of the electrode finger 25. The upper side on the cross-section of the mass-adding film 28 in this case is substantially close to a point. Such a shape is realized by for example the surface tension of the material when the material which becomes the mass-adding film 28 is formed by printing on the electrode finger 25.

Note that, in the SAW elements in FIG. 8D to FIG. 8F, the electrode fingers are formed as trapezoidal electrode fingers 25, but may be rectangular electrode fingers 13b as well.

In all of the mass-adding films in FIG. 8D to FIG. 8F, in the same way as the mass-adding films 9, by making the upper surface side portions narrower than the lower surface side portions, the mass of the mass-adding films is reduced at the boundary between the region in which the electrode fingers 25 are arranged and the region in which they are not arranged. As a result, any mass-adding film exhibits the action of making the transition of the vibration center of SAW from the substrate 3 to the mass-adding film gentler in the same way as the mass-adding films 9, consequently the electromechanical coupling factor K² is improved.

(Preferred Material and Thickness of Mass-Adding Films)

Below, the preferred material and thickness “t” of the mass-adding films 9 are studied. Note, in the simulation in the following study, the mass-adding films are formed in rectangles (the mass-adding films 309 in the third comparative example). However, the mass-adding films 9 are obtained by improving the mass-adding films 309, therefore the preferred material and thickness in the mass-adding films 309 are the preferred material and thickness also in the mass-adding films 9.

Further, in the following study, among the actions exhibited by the mass-adding films, the action of increase of the reflection coefficient is focused on. Note, it is confirmed everywhere that the preferred material and thickness set by focusing on the action of increase of the reflection coefficient are preferred ones concerning the electromechanical coupling factor K² as well.

In the following study, so long not otherwise indicated, the substrate 3 is the 128° Y-X cut LiNbO₃ substrate, the IDT electrode 5 is made of Al, and the protective layer 11 is made of SiO₂.

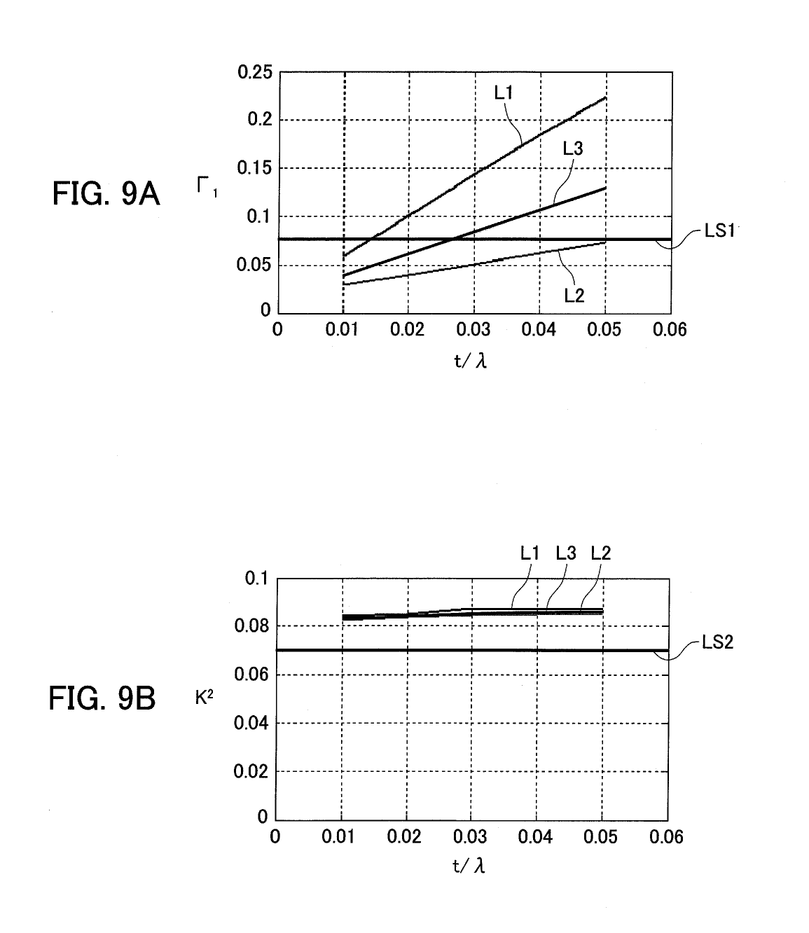

FIG. 9A and FIG. 9B are graphs showing the reflection coefficient Γ₁ per electrode finger 13b and the electromechanical coupling factor K².

FIG. 9A and FIG. 9B ware obtained by simulation. The computation conditions were as follows.

Normalized thickness e/λ of IDT electrode 5: 0.08
Normalized thickness T/λ of protective layer 11: 0.25
Normalized thickness t/λ of mass-adding films 309: Changed within a range of 0.01 to 0.05.
Material of mass-adding films 309: WC, TiN, TaSi₂
Acoustic impedances of materials (unit is MRayl):
SiO₂: 12.2 Al: 13.5
WC: 102.5 TiN: 56.0 TaSi₂: 40.6

In FIG. 9A and FIG. 9B, the abscissa shows the normalized thickness t/λ of the mass-adding films 309. In FIG. 9A, the ordinate shows the reflection coefficient Γ₁ per electrode finger 13b. In FIG. 9B, the ordinate shows the electromechanical coupling factor K².

In FIG. 9A and FIG. 9B, lines L1, L2, and L3 correspond to the cases where the mass-adding films 309 are made of WC, TiN, and TaSi₂. In FIG. 9A, a line LS1 shows the lower limit of the generally preferred range of the reflection coefficient Γ₁. In FIG. 9B, a line LS2 shows the lower limit of the generally preferred range of the electromechanical coupling factor K².

It was confirmed from these diagrams that, by provision of the mass-adding films 309, it was possible to keep the reflection coefficient Γ₁ in the generally preferred range while keeping the electromechanical coupling factor K² in the generally preferred range.

Further, it is suggested from these diagrams that, the larger the normalized thickness t/λ of the mass-adding films 309, the higher the reflection coefficient Γ₁ and electromechanical coupling factor K². Such a tendency occurs no matter what the material is used to form the mass-adding films 309.

In general, the larger the difference of acoustic impedance among the media through which sound wave is propagated, the larger the reflection wave. However, with TaSi₂ (line L3), compared with TiN (line L2), irrespective of the fact that the acoustic impedance is small and the difference of the acoustic impedance from SiO₂ is small, the reflection coefficient Γ₁ becomes large. Below, the reason for this is studied.

The reflection coefficients Γ₁ and the electromechanical coupling factors K² were computed for cases (Case No. 1 to No. 7) where the mass-adding films 309 were formed by various hypothetical materials having acoustic impedances Zₛ which were the same as each other, but having Young's moduli E and densities p which were different from each other.

The computation conditions were as follows.

Normalized thickness e/λ of IDT electrode 5: 0.08
Normalized thickness T/λ of protective layer 11: 0.30
Normalized thickness t/λ of mass-adding films 309: 0.03
Physical property values of mass-adding films 309:

| | Z_{S} | E | ρ |
|---|---|---|---|
| | (MRayl) | (GPa) | (10³ kg/m³) |
| No. 1: | 50 | 100 | 25.0 |
| No. 2: | 50 | 200 | 12.5 |
| No. 3: | 50 | 300 | 8.33 |
| No. 4: | 50 | 400 | 6.25 |
| No. 5: | 50 | 500 | 5.00 |
| No. 6: | 50 | 600 | 4.17 |
| No. 7: | 50 | 700 | 3.57 |

Note that, Z_{S} = √(ρE)

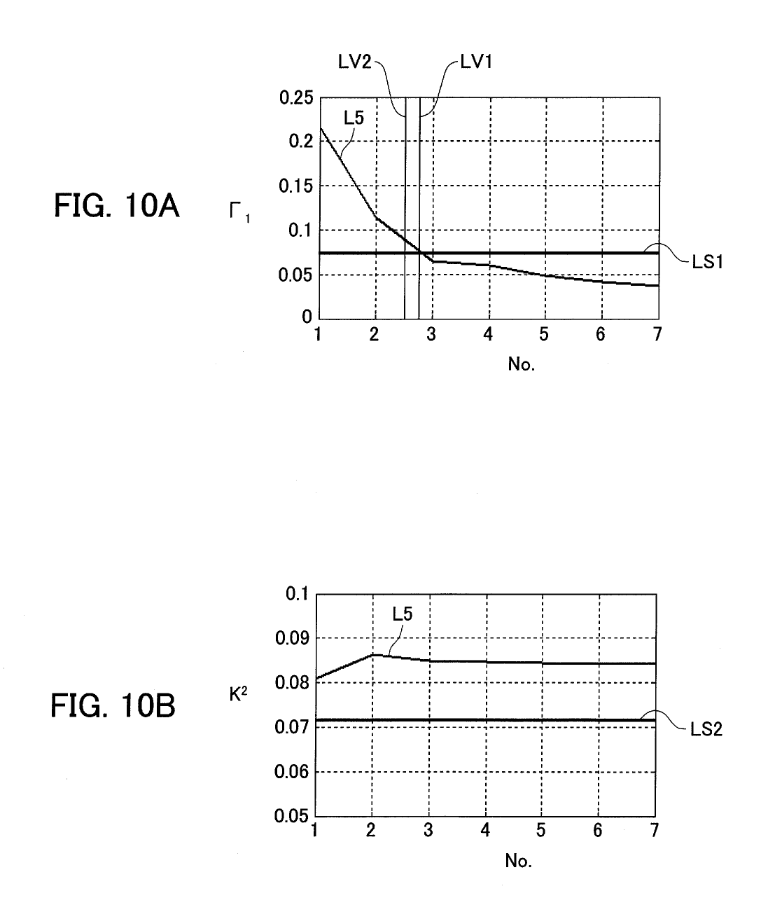

FIG. 10A and FIG. 10B are graphs showing the results of computation based on the above conditions. The abscissa shows the “No.”, while the ordinate shows the reflection coefficient Γ₁ per electrode finger 13b or the electromechanical coupling factor K². The line L5 shows the computation results.

In FIG. 10A, even when the acoustic impedances Zₛ are the same, the smaller the Young's modulus E, while the larger the density ρ, the larger the reflection coefficient Γ₁. Further, the ratio of change of the reflection coefficient Γ₁ in No. 1 to No. 3 becomes larger than the ratio of change of the reflection coefficient Γ₁ in No. 3 to No. 7. In other words, near No. 3, there is room for finding the critical significance.

It is considered that such a change of reflection coefficient Γ₁ is caused due to a difference of the propagation velocity of the acoustic wave among the materials configuring the mass-adding films 309. First, by waveguide theory, the vibration distribution becomes larger in a region of a medium having a slower propagation velocity of the acoustic wave. On the other hand, the propagation velocities V of acoustic waves in the hypothetical materials No. 1 to No. 7 become as follows (unit: m/s). Note that, V=√(E/ρ).

### No. 1: 2000 No. 2: 4000 No. 3: 6000

### No. 3: 8000 No. 4: 10000 No. 6: 12000

### No. 7: 14000

Accordingly, it is considered that, even in the mass-adding films 309 which have equivalent acoustic impedances, it is believed that the reflection coefficient becomes effectively higher in the mass-adding film 309 having a slow propagation velocity of the acoustic wave in which the vibration distribution is concentrated to the mass-adding film 309 than a mass-adding film 309 having a fast propagation velocity of the acoustic wave in which the vibration distribution is dispersed to the periphery.

Further, the propagation velocity of the acoustic wave of SiO₂ is 5560 m/s, and the propagation velocity of the acoustic wave of Al is 5020 m/s. Accordingly, the propagation velocities of the acoustic wave of the mass-adding films 309 in No. 1 and No. 2 are slower than the propagation velocities of the acoustic wave through the protective layer 11 and IDT electrode 5, and the propagation velocities of the acoustic wave of the mass-adding films 309 in No. 3 to No. 7 are faster than the propagation velocities of the acoustic wave through the protective layer 11 and IDT electrode 5. Accordingly, the change of the ratio of change of the reflection coefficient near No. 3 explained above can also be explained by the propagation velocities of the acoustic wave.

Note that, in FIG. 10A, the propagation velocities of the acoustic wave of SiO₂ and Al when regarding the abscissa as the propagation velocity of the acoustic wave are indicated by lines LV1 and LV2. Further, the electromechanical coupling factor K² shown in FIG. 10B is kept in the preferred range even if the Young's modulus and density ρ change.

As described above, the mass-adding films 309 is preferably made of a material which has a different acoustic impedance from the materials forming the protective layer 11 and the IDT electrode 5 and which has a slower propagation velocity of the acoustic wave than the materials forming the protective layer 11 and the IDT electrode 5. Note that, materials having acoustic impedances larger than the materials forming the protective layer 11 and the IDT electrode 5, compared with materials having smaller acoustic impedances, tend to satisfy the condition that the propagation velocity of the acoustic wave is slower than the materials forming the protective layer 11 and the IDT electrode 5, and are easily selected.

As such a material, for example, there can be mentioned Ta₂O₅, TaSi₂, and W₅Si₂. Their physical property values (acoustic impedance Zₛ, propagation velocity V of acoustic wave, Young's moduli E, and density ρ) are as follows.

| | ZS | V | E | ρ |
|---|---|---|---|---|
| | (MRayl) | (m/s) | (GPa) | (10³ kg/m³) |
| Ta2O5: | 33.8 | 4352 | 147 | 7.76 |
| TaSi2: | 40.6 | 4438 | 180 | 9.14 |
| W5Si2: | 67.4 | 4465 | 301 | 15.1 |

Note that, WC and TiN exemplified in FIG. 9A do not satisfy the condition that the propagation velocity of the acoustic wave be slower than the materials forming the protective layer 11 and the IDT electrode 5 (V of WC: 6504 m/s, V of TiN: 10721 m/s).

The reflection coefficient was calculated for Ta₂O₅ (difference of acoustic impedance between it and Al or SiO₂ is about 20 MRayl) which has an acoustic impedance further closer to the acoustic impedances of the protective layer 11 and the IDT electrode 5 than even TaSi₂ (FIG. 9A, line L3) to confirm the above knowledge about the materials.

The calculation conditions were as follows.

Normalized thickness e/λ of IDT electrode 5: 0.08
Normalized thickness T/λ of protective layer 11: 0.27, 0.30, or 0.33
Normalized thickness t/λ of mass-adding film 309: Changed within a range of 0.01 to 0.09.

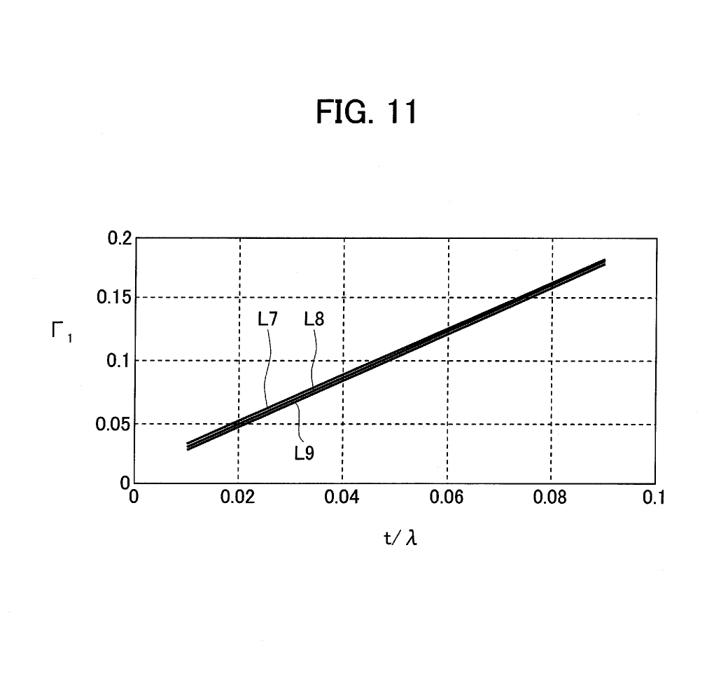

FIG. 11 is a graph which shows the results of calculation based on the above conditions. The abscissa and ordinate are same as the ordinate and abscissa in FIG. 9A. Note that, lines L7, L8, and L9 respectively correspond to cases where the normalized thicknesses T/λ of the protective layer 11 are 0.27, 0.30, and 0.33 (lines L7, L8, and L9 are substantially superimposed on each other).

In FIG. 11, with Ta₂O₅, compared with TiN (FIG. 9A, line L2), irrespective of the fact that the acoustic impedance is close to the acoustic impedance of the protective layer 11, the propagation velocity of the acoustic wave is slow, therefore the reflection coefficient becomes high.

FIG. 11 shows that the normalized thickness T/λ of the protective layer 11 generally does not exert an influence upon the reflection coefficient.

Next, the preferred range of the normalized thickness t/λ of the mass-adding film 309 is studied. First, the lower limit value of the preferred range of the normalized thickness t/λ of the mass-adding film 309 (hereinafter sometimes “of the preferred range” is omitted and the “lower limit value” is simply referred to) is studied.

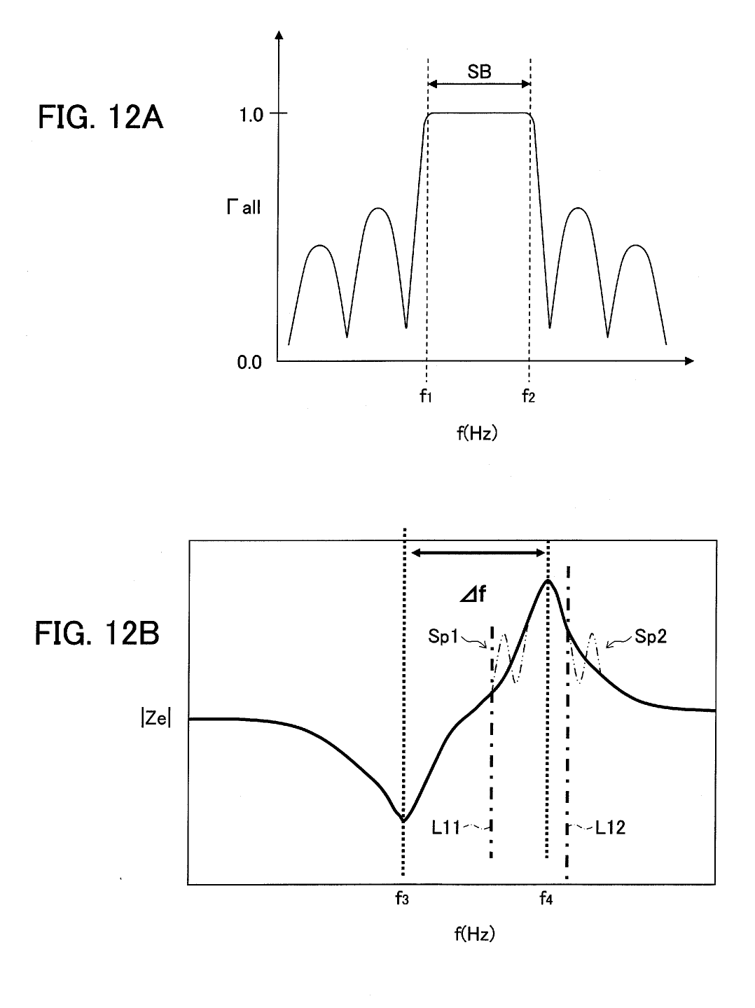

FIG. 12A is a graph which substantially shows the reflection coefficient Γₐₗₗ of the IDT electrode 5 (all electrode fingers 13b). In FIG. 12A, the abscissa shows the frequency f, and the ordinate shows the reflection coefficient Γₐₗₗ.

The frequency band (f₁ to f₂) in which the reflection coefficient Γₐₗₗ substantially becomes 1 (100%) is called the “stop band”. Note that, in practical use, the reflection coefficient Γₐₗₗ in the stop band does not have to be exactly 1. For example, a frequency band in which the reflection coefficient Γₐₗₗ is 0.99 or more may be specified as the stop band. Further, in general, at the lower end f₁ and upper end f₂ of the stop band, the reflection coefficient Γₐₗₗ rapidly changes, therefore the interval between these changes may be specified as the stop band as well.

The reflection coefficient Γₐₗₗ of the IDT electrode is determined by the reflection coefficient Γ₁ per electrode finger 13b and the number of electrode fingers 13b and so on. Further, as generally known, the smaller the reflection coefficient Γ₁, the smaller the width SB of the stop band.

FIG. 12B is a graph which substantially shows an electrical impedance Ze of the IDT electrode 5.

In FIG. 12B, the abscissa shows the frequency “f”, and the ordinate shows the absolute value |Ze| of the impedance. As generally known, |Ze| takes the minimum value at the resonant frequency f₃ and takes the maximum value at the antiresonant frequency f₄. Further, when the normalized thickness t/λ of the mass-adding film 309 is changed, the upper end f₂ of the stop band and the antiresonant frequency f₄ change in a state where the lower end f₁ of the stop band and the resonant frequency f₃ coincide. The ratio of change at this time is larger in the upper end f₂ of the stop band than the resonant frequency f₄.

Here, when assuming that the upper end f₂ of the stop band is a frequency indicated by the line L11 which is lower than the antiresonant frequency f₄, as indicated by an imaginary line (two dotted chain line) in a region Sp1, a spurious wave is generated in a frequency band (width Δf) between the resonant frequency f₃ and the antiresonant frequency f₄. As a result, the desired filter characteristics etc. are liable to not be obtained.

On the other hand, when assuming that the upper end f₂ of the stop band is a frequency indicated by the line L12 which is higher than the antiresonant frequency f₄, as indicated by the imaginary line (two dotted chain line) in a region Sp2, a spurious wave is generated at a frequency higher than the antiresonant frequency f₄. In this case, the influence of the spurious wave exerted upon the filter characteristic etc. is suppressed.

Accordingly, the upper end f₂ of the stop band is preferably a higher frequency than the antiresonant frequency f₄. Here, the upper end f₂ of the stop band depends upon the reflection coefficient, therefore the reflection coefficient of the IDT electrode 5 may be adjusted so that the upper end f₂ of the stop band becomes a frequency higher than the antiresonant frequency f₄. Further, the reflection coefficient of the IDT electrode 5 linearly increases as the normalized thickness t/λ of the mass-adding film 309 becomes larger as shown in FIG. 9 and FIG. 11. Therefore, by adjusting the normalized thickness t/λ of the mass-adding film 309, the upper end f₂ of the stop band can be made a frequency higher than the antiresonant frequency f₄. That is, by adjusting the normalized thickness t/λ of the mass-adding film 309 to a thickness so that the upper end f₂ of the stop band becomes higher than the antiresonant frequency f₄, generation of a spurious wave is suppressed in the frequency band (width Δf) between the resonant frequency f₃ and the antiresonant frequency f₄.

Here, as shown in FIG. 11, the reflection coefficient Γ₂ is influenced by the normalized thickness T/λ of the protective layer 11. Further, the width Δf is influenced by the normalized thickness T/λ of the protective layer 11. Therefore, the normalized thickness t/λ of the mass-adding film 309 is preferably determined in accordance with the normalized thickness T/λ of the protective layer 11.

Therefore, the normalized thickness t/λ by which the upper end f₂ of the stop band becomes equivalent to the antiresonant frequency f₄ was calculated by changing the normalized thickness T/λ of the protective layer 11. Based on the calculated result, the lower limit value of the normalized thickness t/λ was defined by the normalized thickness T/λ.

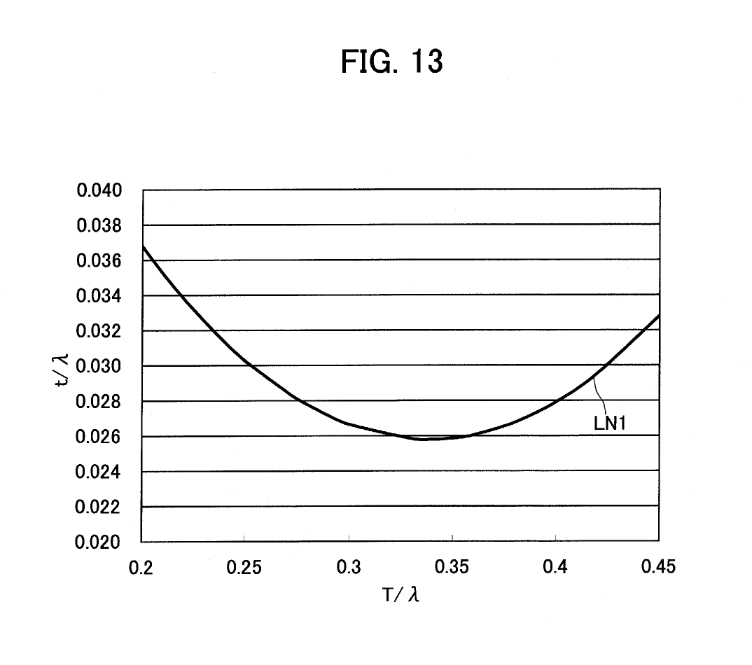

FIG. 13 is a graph for explaining normalized thickness t/λ by which the upper end f₂ of the stop band becomes higher than the antiresonant frequency f₄ and takes as an example the case where the material of the mass-adding film 309 is Ta₂O₅.

In FIG. 13, the abscissa shows the normalized thickness T/λ of the protective layer 11, and the ordinate shows the normalized thickness t/λ of the mass-adding film 309. The solid line LN1 shows the calculated results of normalized thickness t/λ with which the upper end f₂ of the stop band becomes equivalent to the antiresonant frequency f₄. Note that, in calculation, the normalized thickness e/λ of the IDT electrode 5 was determined to 0.08λ.

As indicated by the solid line LN1, for the normalized thickness t/λ with which the upper end f₂ of the stop band becomes equivalent to the antiresonant frequency f₄, approximation curve could be suitably derived by second order curve.

Specifically, this is as follows.

### Ta₂O₅:

t/λ=0.5706(T/λ)²−0.3867T/λ+0.0913

### TaSi₂:

t/λ=0.3995(T/λ)²−0.2675T/λ+0.0657

### W₅Si₂:

t/λ=0.2978(T/λ)²−0.1966T/λ+0.0433

Note that, in all equations of the lower limit value, the minimum value of the normalized thickness t/λ is larger than the largest value (0.01) of the normalized thickness of the bonding layer shown in Patent Literature 2. In Patent Literature 1, the thickness of the bonding layer is not normalized by wavelength, therefore comparison is difficult. However, even when the frequency is made high (for example the largest frequency of UMTS is 2690 MHz) and the propagation velocity of acoustic wave is made slow (for example 3000m/s) so that the normalized thickness becomes large, λ=1.1 μm, and the largest value (100 Å) of the thickness of the bonding layer in Patent Literature 1 is less than 0.01 when normalized.

Next, the upper limit value of the preferred range (hereinafter, sometimes “of the preferred range” is omitted and the “upper limit value” is simply referred to) of the normalized thickness t/λ of the mass-adding films 309 is studied.

As shown in FIG. 9A and FIG. 11, the larger the normalized thickness t/λ of a mass-adding film 309, the higher the reflection coefficient. Accordingly, the upper limit value of the normalized thickness t/λ is in a range so that the mass-adding films 309 are not exposed from the protective layer 11.

In the same way as the lower limit value of the normalized thickness t/λ, when the upper limit value of the normalized thickness t/λ is defined according to an equation, for example, this can be defined as in the following equation by estimating the normalized thickness e/λ of the IDT electrode 5 as less than 0.1 in comparison with the normalized thickness e/λ in the general SAW element.

Upper limit value: t/λ=T/λ−0.1

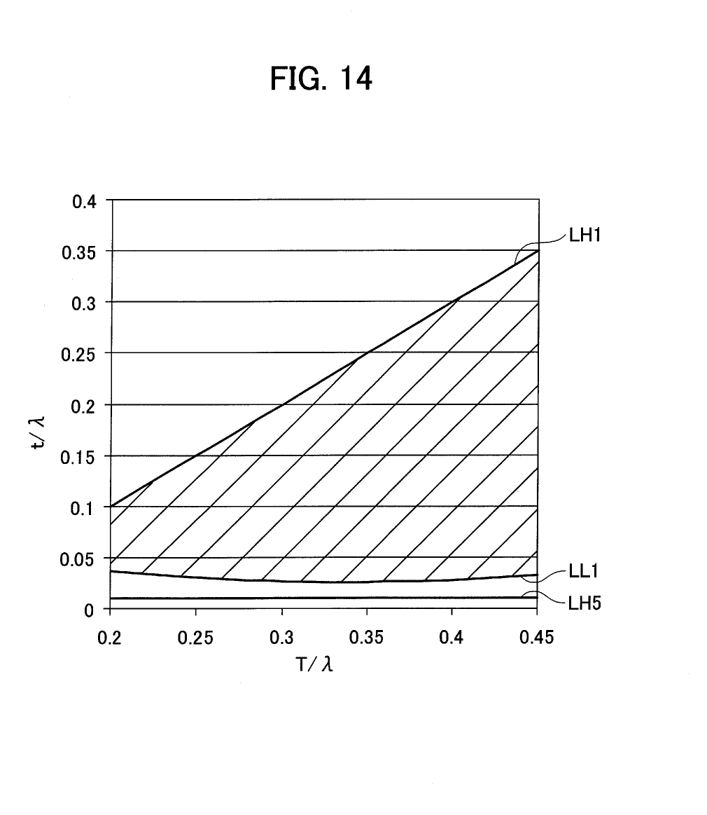

The preferred range of the normalized thickness t/λ derived from the above study is shown in FIG. 14 by taking as an example Ta₂O₅. In FIG. 14, the abscissa and ordinate show the normalized thickness T/λ of the protective layer 11 and the normalized thickness t/λ of the mass-adding film 309 in the same way as FIG. 13. A line LL1 shows the lower limit value (corresponding to the line LN1 in FIG. 3), and a line LH1 shows the upper limit value. A hatched region between these lines is the preferred range of the normalized thickness t/λ of the mass-adding film 309. Note that, a line LH5 shows the upper limit value (0.01) of the bonding layer indicated in Patent Literature 2.

(Configuration of SAW Device)

FIG. 15 is a cross-sectional view which shows a SAW device 51 according to the present embodiment.

The SAW device 51 configures for example a filter or duplexer. The SAW device 51 has a SAW element 31 and a circuit board 53 on which the SAW element 31 is mounted.

The SAW element 31 is for example configured as a SAW element of a so-called wafer level package. The SAW element 31 has the SAW element 1 explained above, a cover 33 which covers the SAW element 1 side of the substrate 3, terminals 35 which pass through the cover 33, and a back surface portion 37 which covers the opposite side to the SAW element 1 of the substrate 3.

The cover 33 is configured by a resin or the like and forms a vibration space 33a for facilitating the propagation of the SAW above the IDT electrode 5 and reflectors 7 (positive side in the z-direction). On the upper surface 3a of the substrate 3, lines 38 which are connected to the IDT electrode 5 and pads 39 which are connected to the lines 38 are formed. The terminals 35 are formed on the pads and are electrically connected to the IDT electrode 5. Though particularly not shown, the back surface portion 37 for example has a back surface electrode for discharging electrical charges charged in the surface of the substrate 3 due to temperature variation etc. and an insulation layer covering the back surface electrode.

The circuit board 53 is configured by a for example so-called rigid type printed circuit board. On a mount surface 53a of the circuit board 53, mount-use pads 55 are formed.

The SAW element 31 is arranged so that the cover 33 side faces the mount surface 53a. Further, the terminals 35 and the mount-use pads 55 are bonded by solder 57. After that, the SAW element 31 is sealed by a seal resin 59.

Note that, in the above embodiments, the substrate 3 is one example of the piezoelectric substrate, and the protective layer 11 is an example of the insulation layer.

The present invention is not limited to the above embodiments and may be worked in various ways.

The acoustic wave element is not limited to a SAW element (in a narrow sense). For example, it may also be a so-called elastic boundary wave element (note, included in a SAW element in a broad sense) in which the thickness of the insulation layer (11) is relatively large (for example 0.5λ to 2λ). Note that, in an elastic boundary wave element, the formation of the vibration space (33a) is unnecessary, and accordingly the cover 33 etc. are unnecessary too.

In the acoustic wave element, the insulation layer (11) is not an essential factor. The insulation layer may be provided for only the purpose of preventing corrosion and may be made thinner than the thickness of the electrode fingers. In these cases as well, for example, by the formation of the mass-adding films by a material having a slower propagation velocity of the acoustic wave than that of the material for the electrode fingers, the reflection coefficient can be made large, and the reflection efficiency of the SAW becomes good, therefore the effect of sealing the SAW in the resonator is improved. Due to this, for example, such effect that a loss can be reduced is exhibited. Further, in these cases as well, in the same way as the embodiment, by the formation of the additional layer so that the upper surface side portion becomes narrower than the lower surface side portion, rapid transition of the vibration center of SAW to the surfaces of the electrode fingers is suppressed, so the effect of improvement of the electromechanical coupling factor is exhibited.

The acoustic wave element is not limited to the wafer level packaged one. For example, in the SAW element, the cover 33 and terminal 35 etc. need not be provided, and the pad 39 on the upper surface 3a of the substrate 3 and the mount-use pad 55 of the circuit board 53 may be directly bonded by solder 57 as well. Further, the vibration space may be formed by a clearance between the SAW element 1 (protective layer 11) and the mount surface 53a of the circuit board 53.

The mass-adding films are preferably provided over the entire surface of the electrode. Note, the mass-adding films may be provided only at a portion of the electrode, for example, may be provided only on the electrode fingers. Further, the mass-adding films may be provided only at portions on the center sides when viewed in the longitudinal directions of the electrode fingers. Furthermore, the mass-adding films may be provided not only on the upper surface of the electrode, but also over the side surfaces. The material of the mass-adding films may be a conductive material or insulation material. Specifically, tungsten, iridium, tantalum, copper, or another conductive material, BaₓSr₁₋ₓO₃, PbₓZn₁₋ₓO₃, ZnO₃, or another insulation material can be mentioned as the materials of the mass-adding films. Further, WC etc. which were not considered to be preferred materials in FIG. 9A may be determined as the materials of the mass-adding films.

By forming the mass-adding films by an insulation material, compared with forming the mass-adding films by a metal material, corrosion of the electrode is suppressed, and the electrical characteristics of the acoustic wave element can be stabilized. The reason for this is as follows: Pinholes are sometimes formed in an insulation layer made of SiO₂. When such pinholes are formed, moisture intrudes up to the electrode portion through them. However, if a metal film made of a material different from the electrode material is arranged on the electrode, corrosion is liable to occur due to a battery effect between dissimilar metals caused by the intruded moisture. Accordingly, if the mass-adding films are formed by insulation material such as Ta₂O₅, almost no battery effect occurs between the electrode and the mass-adding films, therefore an acoustic wave element suppressed in corrosion of electrode, so having a high reliability can be obtained.

The upper surface of the insulation layer (11) may have concave-convex shapes so as to form projecting shapes at the positions of the electrode fingers. In this case, the reflection coefficient can be made further higher. The concave-convex shapes may be formed due to the thickness of the electrode fingers at the time of formation of the protective layer as explained with reference to FIG. 2E or may be formed by etching the surface of the insulation layer in the region between the electrode fingers.

For the substrate, other than the 128°±10° Y-X cut LiNbO₃ substrate, for example, use can be made of 38.7°±Y-X cut LiTaO₃ etc. The material of the electrode (electrode fingers) is not limited to Al and an alloy containing Al as the major component and may be for example Cu, Ag, Au, Pt, W, Ta, Mo, Ni, Co, Cr, Fe, Mn, Zn, or Ti. The material of the insulation layer is not limited to SiO₂, but may be for example a silicon oxide other than SiO₂.

### REFERENCE SIGNS LIST

1 . . . SAW element (acoustic wave element), 3 . . . substrate (piezoelectric substrate), 3a . . . upper surface, 5 . . . IDT electrode (electrode), 9 . . . first film, and 11 . . . protective layer (insulation layer).

1. An acoustic wave element, comprising:
a piezoelectric substrate;
electrode fingers on an upper surface of the piezoelectric substrate; and
mass-adding films on upper surfaces of the electrode fingers,
wherein, when viewing cross-sections perpendicular to the extending directions of the electrode fingers, the mass-adding films have the narrowest widths at an upper sides in the cross-sections.

2. The acoustic wave element according to claim 1, further comprising:
an insulation layer which
covers the electrode fingers on which the mass-adding films are arranged and a portion of the upper surface of the piezoelectric substrate which is exposed from the electrode fingers and
has a thickness from the upper surface of the piezoelectric substrate is larger than a total thickness of the electrode fingers and mass-adding films.

3. The acoustic wave element according to claim 2, wherein the insulation layer contains a silicon oxide as a major component.

4. The acoustic wave element according to claim 2, wherein the mass-adding films contain a material as a major component, the material having a larger acoustic impedance than those of material of the electrode fingers and material of the insulation layer and having a slower propagation velocity of the acoustic wave than those of the material of the electrode fingers and the material of the insulation layer.

5. The acoustic wave element according to claim 1, wherein the mass-adding films comprise an insulation material as a major component.

6. The acoustic wave element according to claim 1, wherein the mass-adding films have trapezoidal shapes in the cross-sections.

7. The acoustic wave element according to claim 6, wherein a ratio of a length of an upper base relative to a length of a lower base in each of the trapezoidal shapes is 0.7 or more and less than 1.0.

8. The acoustic wave element according to claim 1, wherein, in the electrode fingers, the side surfaces along the longitudinal direction of the electrode fingers are inclined and expand with respect to one another as the side surfaces approaching the upper surface of the piezoelectric substrate.

9. An acoustic wave device, comprising:
an acoustic wave element according to claim 1; and
a circuit board to which the acoustic wave element is attached.
